(19) United States
(12) Patent Application Publication
(10) Pub. No.: US 2003/0158826 A1
(43) Pub. Date: Aug. 21, 2003

(54) METHODS AND APPARATUS FOR A UTILITY PROCESSING SYSTEM

(76) Inventors: MICHAEL C. BURKE, WHITTIER, CA (US); RONALD K. RYAN, APPLE VALLEY, CA (US)

Correspondence Address: SNELL & WILMER, ONE ARIZONA CENTER, 400 EAST VAN BUREN, PHOENIX, AZ, 850040001

(21) Appl. No.: 09/267,176

(22) Filed: Mar. 12, 1999

Related U.S. Application Data
(60) Provisional application No. 60/077,935, filed on Mar. 13, 1998.

(51) Int. Cl. G01R 11/56

(52) U.S. Cl. 705/412

(57) ABSTRACT

A utility processing system includes a utility processor which accepts utility metering and pricing data as inputs and outputs consumption decisions and usage and billing information. In accordance with one aspect of the invention, the utility processor obtains metering data from utility meters located at remote consumer facilities and obtains utility pricing data from the Internet. The utility processor then uses an optimization algorithm to determine an optimum consumption decision. In accordance with another aspect of the invention, the optimum consumption decision can include purchasing electricity from the grid, generating electricity using a Distributed Generation (“DG”) system, conserving electricity using a Demand-Side Management (“DSM”) system, and switching to alternative fuel sources. In accordance with still another aspect of the invention, the utility processor provides various pricing, billing, and usage data to customers.

The present invention claims the benefit of U.S. Provisional Application No. 60/077935, filed on Mar. 13, 1998.

### BACKGROUND OF THE INVENTION

1. Field of the Invention

The present invention generally relates to methods and apparatus for automatically managing energy costs using a utility processing system. More particularly, the present invention relates to a method and apparatus for managing energy costs by automatically optimizing energy consumption, purchasing, and generation decisions based on energy usage and pricing data.

2. Description of the Related Art

For a century, the electric power industry in the United States has been highly regulated. Local and state utility commissions set rates that power companies charged their customers. Federal agencies regulated interstate sale of electric power and governed the design and licensing of power plants. As a result, a small number of large privately-owned power companies, also known as electric utilities, acting as virtual monopolies dominated the electric power industry.

Recently, a movement toward deregulation of the electric power industry is providing tremendous entrepreneurial opportunities to deliver energy to customers in new and innovative ways.

Energy customers may attempt to use different types of energy sources depending on their relative prices. For example, a customer using electricity to heat a facility may switch to natural gas heating. However, switching energy sources may be cost prohibitive. New equipment may need to be purchased in order to use the new energy source. Switching between energy sources also is time intensive. By the time a customer has completed switching from one energy source to another, the price incentive for making the switch may no longer exist.

Energy customers also may attempt to generate electricity at their own facilities in order to supplement or replace electricity purchased from utilities. Deciding when to generate or purchase electricity is a very complicated decision. A customer would need to constantly compare the cost of generating electricity at the facilities to the fluctuating price of electricity.

Therefore, a new method and apparatus which overcomes the various shortcomings of conventional methods is needed to permit customers to automatically manage their energy costs.

### SUMMARY OF THE INVENTION

The present invention describes methods and apparatus for managing energy costs by automatically optimizing energy consumption, purchasing, and generation decisions based on energy usage and pricing data. In accordance with an exemplary embodiment of the present invention, a utility processing system includes a utility processor which accepts utility metering and pricing data as inputs and outputs consumption decisions and usage and billing information. In accordance with one aspect of the invention, the utility processor obtains metering data from utility meters located at remote consumer facilities and obtains utility pricing data from the Internet. The utility processor then uses an optimization algorithm to determine an optimum consumption decision. In accordance with another aspect of the invention, the optimum consumption decision can include purchasing electricity from the grid, generating electricity using a Distributed Generation (“DG”) system, conserving electricity using a Demand-Side Management (“DSM”) system, and switching to alternative fuel sources. In accordance with still another aspect of the invention, the utility processor provides various pricing, billing, and usage data to customers.

### BRIEF DESCRIPTION OF THE DRAWING FIGURES

The subject matter of the present invention is particularly pointed out and distinctly claimed in the concluding portion of the specification. The present invention, however, both as to organization and method of operation, may best be understood by reference to the following description taken in conjunction with the claims and the accompanying drawing figures, in which like parts may be referred to by like numerals:

FIG. 1 is a schematic of an exemplary utility processing system in accordance with various aspects of the present invention;

FIG. 2 is a schematic of a portion of the exemplary utility processing system shown in FIG. 1;

FIG. 3 is a schematic of another portion of the exemplary utility processing system shown in FIG. 1;

FIG. 4 is a schematic of still another portion of the exemplary utility processing system shown in FIG. 1;

FIG. 5 is a schematic of yet another portion of the exemplary utility processing system shown in FIG. 1;

FIG. 6 is a schematic of still yet another portion of the exemplary utility processing system shown in FIG. 1; and

FIG. 7 is a schematic of an exemplary implementation of an exemplary utility processing system in accordance with various aspects of the present invention.

### DETAILED DESCRIPTION OF PREFERRED EMBODIMENTS OF THE INVENTION

In order to provide a more thorough understanding of the present invention, the following description sets forth numerous specific details, such as specific process steps, process parameters, components, etc. It should be appreciated, however, that these specific details need not be employed to practice the present invention.

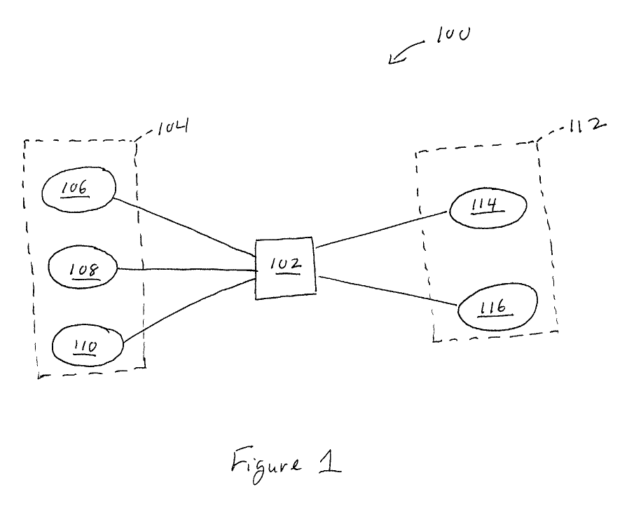

In a broad sense, with reference to FIG. 1, a utility processing system 100 according to various aspects of the present invention includes a utility processor 102 with inputs 104 and outputs 112. More particularly, input 104 into utility processor 102 in accordance with an exemplary embodiment of the present invention includes utility metering data 106, utility pricing data 108, and forecasting data 110. Output 112 from utility processor 102 includes consumption optimization decisions 114 and usage and billing information 116. It should be appreciated, however, that input 104 and output 112 can include various utility-related data and consumption decisions and information depending on the particular application. Additionally, as will be described in greater detail below, it should be appreciated that the utility processing system 100 schematically depicted in FIG. 1 can be implemented using a vast array of computer hardware and software configurations.

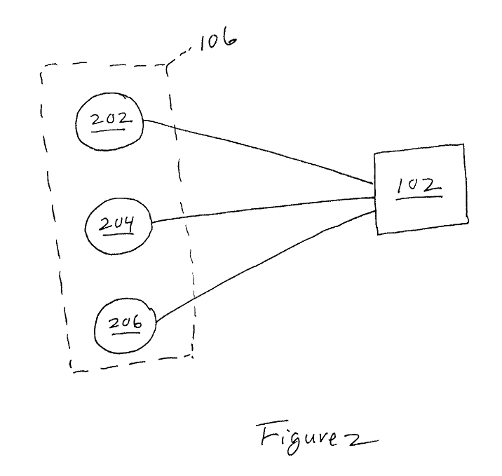

With reference to FIG. 2, in accordance with one aspect of the present invention, utility metering data 106 includes usage data obtained from utility meters, such as electric meter 202, gas meter 204, water meter 206, and the like. For the sake of simplicity, the following description relates specifically to electric meters 202. It should be appreciated, however, that such description is not intended as a limitation on the use or applicability of the present invention, but is instead provided to enable a full and complete description of the exemplary embodiment.

Electric meter 202 is suitably configured to communicate electricity usage data to utility processor 102 periodically or upon request by a requesting system (not shown). In the present exemplary embodiment, electric meter 202 is preferably configured to provide electricity usage data automatically and remotely. For example, the VECTRON meter produced by Schlumberger is an automated electric meter capable of accessing a telephone line and remotely, periodically and automatically transmitting metering data. It should be appreciated, however, that various automated meters may be used depending on the particular application.

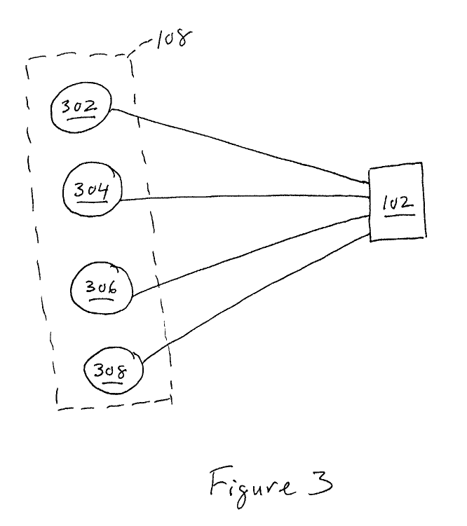

With reference to FIG. 3, in accordance with another aspect of the present invention, utility pricing data 108 suitably includes price point data associated with various sources of power, such as grid price point data 302, Distributed Generation (“DG”) price point data 304, Demand-Side Management (“DSM”) price point data 306, alternative fuel price point data 308, and the like. Grid price point data 302 preferably reflects the price of purchasing a unit of electricity from the grid (i.e., the utility). As will be described in greater detail below, DG price point data 304 preferably reflects the price of generating a unit of electricity using a DG system such as a microturbine to independently generate electricity rather than purchase electricity. Also, as will be described in greater detail below, DSM price point data 306 preferably reflects the cost saving associated with controlling consumption of energy using a DSM control system. Furthermore, alternative fuel price point data 308 preferably reflects the price of using an alternative fuel source, such as natural gas, solar power, window power, and the like.

In the present exemplary embodiment, grid price point data 302, DG price point data 304, DSM price point data 306, and alternative fuel price point data 308 are preferably obtained electronically through the Internet using Transmission Control Protocol-Internet Protocol (“TCP-IP”). For example, in California, these price point data can be obtained from the California Power Exchange at Uniform Resource Locator (“URL”) “www.calpx.com”, the California Independent System Operator (“ISO”) at URL “www.caiso.com”, natural gas prices at URL “www.gasearch.com”, and fuel oil and other petro prices at URL “www.petroleumargus.com”. It should be appreciated, however, that the preceding Internet sites are provided for exemplary purposes only and that utility price point data can be obtained from various Internet sites, publications, utility pricing services, and the like.

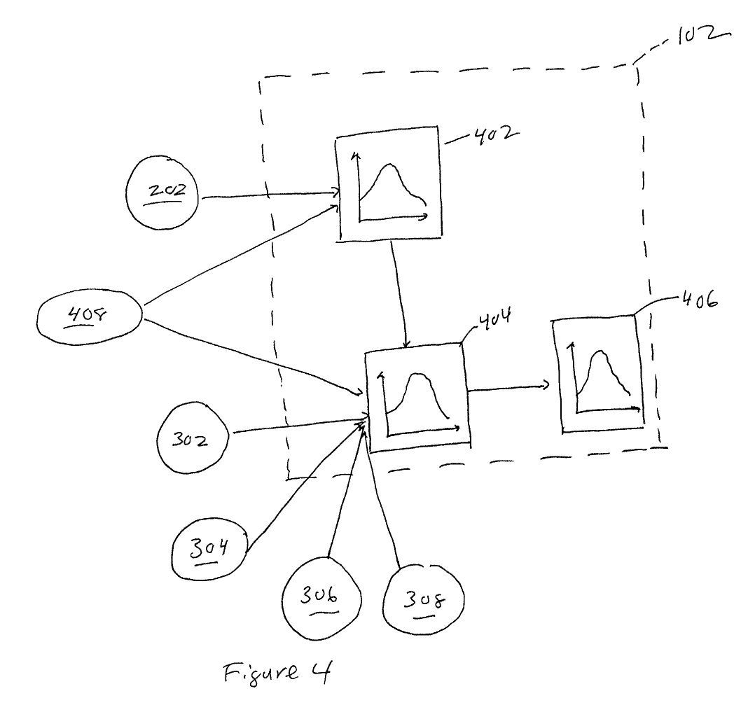

Having thus obtained the various metering and price point data, the utility processor 102 according to various aspects of the present invention uses an optimization algorithm to make various consumption decisions. With reference to FIG. 4, the metering data obtained from electric meter 202 is used to form a forecast load shape 402. More particularly, meter readings are obtained from electric meter 202 at predetermined intervals, such as every hours, half hour, quarter hour, 5 minutes, and the like. In an exemplary embodiment, the meter readings are preferably obtained at the same intervals at which the price point data is available. For example, if the various price point data described above can be obtained at 15 minute intervals, then meter readings are also obtained at 15 minute intervals. In this manner, a data set (i.e., a load shape) is suitably obtained of electricity usage over a period of time. The current load shape is then preferably combined with a load shape from a prior period of time, such as the prior days load shape, then compared to prior stored load shapes in order to obtain a forecast of the load demand for the next interval of time (i.e., the load forecast). It should be recognized, however, that various methods can be used to obtain the load forecast.

The load forecast is then used to obtain a price baseline based on the price point data. For example, if the load forecast for the next interval of time is X kilowatt-hours (kWh) of electricity, then cost baselines are obtained for the various sources of power, such as those described earlier (i.e., buying from the grid, generating electricity using a DG system, conserving energy using a DSM control system, switching to alternative fuel sources, and the like). More particularly, with reference again to FIG. 4, a price baseline is obtained using the grid price point data 302 for meeting all of the X kWh of demand using electricity purchased from the grid; a price baseline is obtained using the DG price point data 304 for meeting all of the X kWh of demand using electricity generated using a DG system; a price baseline is obtained using the DSM price point data 306 for meeting all of the X kWh of demand by conserving electricity using a DSM control system; and a price baseline is obtained using the alternative fuel price data 308 for meeting all of the X kWh of demand using alternative fuel sources.

Additionally, price baselines are obtained for meeting the X kW of demand using a mix of the four sources. For example, a price baseline is obtained using the grid price point data 302 and DG price point data 304 for meeting 30 percent of the X kWh of demand using electricity purchased from the grid and 70 percent of the X kWh of demand using electricity generated using a DG system. By comparing the various price baselines, an optimal cost curve 406 can be obtained which determines the most cost effective means of meeting the forecasted load. A feedback system can also be implemented such that if the actual load deviates from the forecasted load, the optimization process outlined above can be iterated to achieve a different cost curve 406 to better meet the actual load.

Furthermore, other forecasting data 408, such as weather data, financial market data, and the like, according to various aspects of the present invention can be used in forecasting a load shape 402 and in deriving a price baseline 404. For example, weather data, which can be obtained from the National Weather Service using the Internet, can help to forecast both the future demand for energy and the future price of energy. A winter storm or a summer heat wave can increase the demand for energy, which in turn can increase the price of energy. Similarly, financial market data, which can also be obtained from various sources using the Internet, can also help to forecast the price of energy. For example, an increase in the price of crude oil can lead to higher electricity and/or gas prices.

Additionally, the various load shapes 402, price baselines 404, and cost curves 406 according to one aspect of the present invention are stored in a database for use in helping to determine a future load forecast. As will be described in greater detail below, the load shapes 402, price baselines 404, and cost curves 406 also can be used in providing metering and billing data to customers.

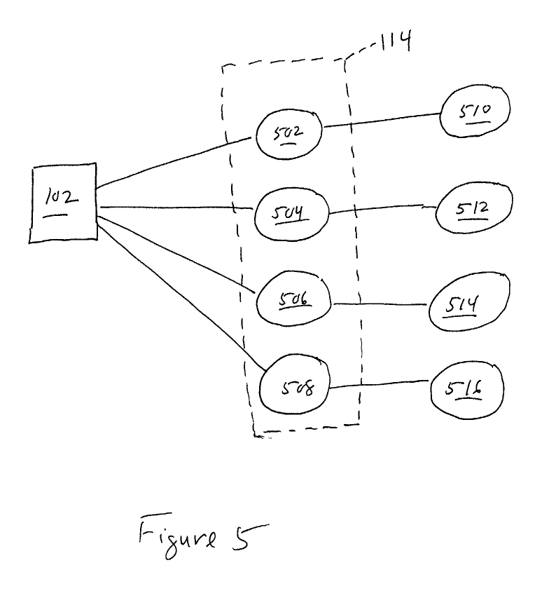

With reference to FIG. 5, having thus determined a cost curve 406, the utility processor 102 implements an appropriate optimal consumption decision 114. For example, as will be described in greater detail below, if the optimal consumption decision 114 includes generating electricity using a DG system, then utility processor 102 issues a consumption decision 502 to suitably operate a DG system. As will be also described in greater detail below, if the optimal consumption decision 114 includes conserving electricity using a DSM control system, then utility processor 102 issues a consumption decision 504 to suitably operate a DSM control system. If the optimal consumption decision 114 includes using an alternative fuel source, then utility processor 102 issues a consumption decision 506 to switch fuel source, for example, from oil to natural gas. If the optimal consumption decision 114 includes buying electricity from a difference source on the grid, then utility processor 102 issues a purchase decision 508 to purchase energy from a different source.

As stated earlier, the utility processor 102 according to various aspects of the present invention can be configured to operate with a DG system to generate electricity. One example of such a DG system is a microturbine which is configured to generate electricity using a variety of fuel sources. For example, the TurboGenerator Power System manufactured by AlliedSignal Power Systems Inc. uses natural gas and can generate 40 to 500 kilowatts of power. The TurboGenerator Power System can be remotely controlled using a SCADA (Supervisory Control and Data Acquisition) system, which includes standardized or proprietary software to monitor and control remote terminal units (RTUs). It should be recognized, however, that various DG systems and various remote control systems can be used depending on the particular application.

As also stated earlier, the utility processor 102 according to various aspects of the present invention can be configured to operate with a DSM control system to conserve electricity. In general, DSM control systems include remotely controlled actuators to turn on or off lights, machinery, and the like to conserve electricity. These remotely controlled actuators can be controlled using any convenient standardized or propriety control system, such as the SCADA system described earlier.

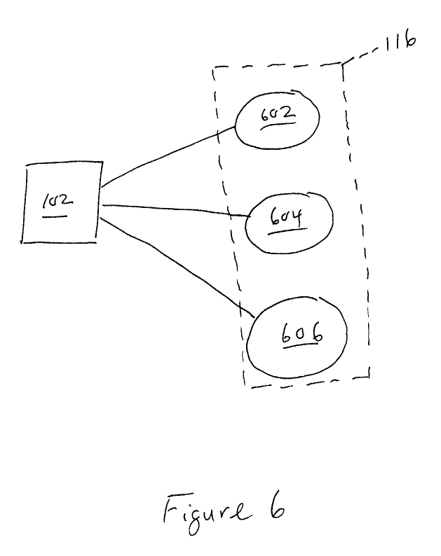

With reference to FIG. 6, the utility processor 102 according to various aspects of the present invention is configured to generate usage and billing information 116. More particularly, in the present exemplary embodiment, utility processor 102 is configured to provide for electronic funds transfer system 602 to provide for electronic payment of bills and configured to generate usage data 604 and billing data 608. The usage data 604 and billing data 608 can include a detailed breakdown of energy use and charges on a yearly, monthly, daily, hourly, or real-time basis. Additionally, the customer can be provided the information in various suitable formats, such as tables or graphs. In the present exemplary embodiment, the usage and billing output 116 are provided on the Internet and the World Wide Web.

As stated above, the present invention can be implemented using a wide variety of computer hardware and software configurations. In the description below, an exemplary implementation of the present exemplary embodiment of the present invention will be described. It should be recognized, however, that such description is not intended as a limitation on the use or applicability of the present invention, but is instead provided to enable a fuller and more complete description of the exemplary embodiment.

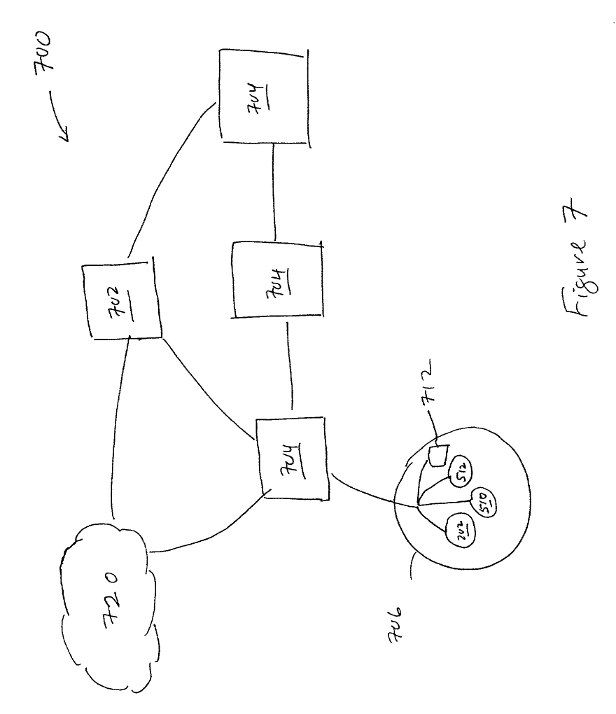

With reference to FIG. 7, in an exemplary embodiment of the present invention, a utility processing system 700 is suitably implemented in a distributed database hierarchy which includes a central server 702 and regional servers 704. In the present exemplary embodiment, central server 702 and regional servers 704 are preferably configured with relational database systems such as Microsoft SQL-Servers, an Oracle servers, and the like. Additionally, central server 702 and regional servers 704 are preferably configured with multi-tasking and multi-threading network operating systems such as Windows NT, Hewlett Packard-UX, Sun Solaris, DEC Unix, and the like. Furthermore, central server 702 and regional servers 704 are preferably networked using any convenient wide area communication method, such as Frame Relay, Asynchronous Transfer Mode (“ATM”), SONET, and the like.

The central server 702 according to various aspects of the present invention is suitably configured to obtain the various price point data described above. In the present exemplary embodiment, central server 702 obtains the various price point data from the Internet 720 as described earlier. Central server 702 then relates the price point data to the regional servers 704. It should be appreciated, however, that regional servers 704 can be configured to obtain the price point data directly from the Internet 720. Alternatively, the price point data can be obtained using a Microsoft Queue Server configured with an Open Financial Exchange (“OFE”) system.

The regional servers 704 according to various aspects of the present invention are connected to one or more customer facilities 706. For sake of convenience, only one regional server 704 will hereinafter be described. A regional servers 704 according to the present exemplary embodiment is preferably connected to an electric meter 202, a DG system 510, a DSM control system 512, and any other suitable remote terminal unit (“RTU”). The regional server 704 suitably communicates with electric meter 202, DM system 510, and DSM system 512 using any convenient data acquisition system such as SCADA, Itron UTS MV90 Data Acquisition, and the like. Additionally, the regional servers 704 communicate with electric meter 202, DG system 510, and DSM system 512 using any convenient data communication medium, such as PSTN, Frame Relay, ATM, TCP-IP, cellular, digital wireless, satellite, and the like. Furthermore, if a customer facility 706 has more than one electric meter 202, they can be connected together using any convenient meter communication medium, such as RS232 interface, KYZ input/output, and the like.

In this manner, metering data from an electric meter 202 is communicated to regional server 704 which then communicates the metering data to central server 702. Central server 702 then retrieves the various price point data to determine an optimal consumption decision. After the optimal consumption decision is made, central server 702 issues the appropriate consumption decision command to regional server 704, which relays the command to the consumer facility 706, for example, to activate the DG system 510 or the DSM control system 512, or to switch the source of energy used or the energy provider. Additionally, a computer terminal 712 at the consumer facility 706 can suitably retrieve the various consumer data provided by the utility system 700, such as metering and billing data.

In accordance with another aspect of the present invention, regional server 704 is configured to carry out the various functions of the central server 702 described above in case of a communication failure or failure of the central server. It should be recognized, therefore, that central server 702 can be eliminated without deviating from the spirit or scope of the present invention. The use of central server 702, however, has the advantage that a central site exists for the various metering, pricing, and billing data used for making the optimization decision.

While exemplary embodiments of the present invention have been shown in the drawings and described above, it should be appreciated that the present invention is not limited to the specific forms shown and described. Various modifications, variations, and enhancements in the design, arrangement, and implementation may be made without departing from the spirit and scope of the present invention set forth herein. For example, rather than a distributed database hierarchy, the present invention can be implemented as a mainframe computer or as a simple “black box” located at the customer facility.

We claim:

1. A method for automatically managing energy cost using metering data and pricing data comprising the steps of:
receiving metering data from an electric meter, wherein the metering data is electronically transmitted from said electric meter;
receiving pricing data, wherein the pricing data is associated with a plurality of sources of power;
forecasting a forecast load based on the received metering data from the electric meter; and
determining an optimal consumption decision based on the received pricing data and the forecast load.
